(19) United States
(12) Patent Application Publication
(10) Pub. No.: US 2010/0134456 A1
(43) Pub. Date: Jun. 3, 2010

(54) ORGANIC ELECTROLUMINESCENT ELEMENT, DISPLAY INCORPORATING ELECTROLUMINESCENT ELEMENT,AND ELECTRICAL GENERATOR

(75) Inventor: Takahito Oyamada, Tsurugshima-Shi (JP)

Correspondence Address: YOUNG & THOMPSON, 209 Madison Street, Suite 500, Alexandria, VA, 22314, US

(73) Assignee: PIONEER CORPORATION, TOKYO (JP)

(21) Appl. No.: 12/532,292

(22) PCT Filed: Mar. 22, 2007
(86) PCT No.: PCT/JP2007/055850

§ 371 Date: Jan. 13, 2010

(51) Int. Cl. G09G 5/00

(52) U.S. Cl. 345/207; 345/81

(57) ABSTRACT

An organic electroluminescent device including an organic electroluminescent layer that is stacked between a plurality of electrodes and emits light by an electric field generated between the plurality of electrodes and, and a power generating semiconductor part that is arranged on the periphery of this organic electroluminescent layer and utilizes from the light emitted by the organic electroluminescent layer an internal light L that has not been emitted from the transparent or semi-transparent electrode to the outside and remains inside in order to generate power by a photoelectric conversion function is provided.

### CROSS-REFERENCE TO RELATED APPLICATION

This is an application PCT/JP2007/55850, filed Mar. 22, 2007, which was not published under PCT article 21(2) in English.

### BACKGROUND OF THE INVENTION

1. Field of the Invention

The present invention relates to an organic electroluminescent device, display device, and power generating device wherein an organic electroluminescent layer emits light by an electric field generated by voltage applied between a plurality of electrodes.

2. Description of the Related Art

In recent years, display devices that employ a so-called organic electroluminescent device have been developed as the next generation display to replace the liquid crystal display. A display that employs such an electroluminescent device (hereinafter “organic EL display”) is capable of achieving high-brightness light emission even at a low voltage.

Such an organic EL display has attracted much attention as a self-luminous planar display device, and emits light with high light emission efficiency based on a simple device structure. Specifically, the organic electroluminescent device of the organic EL display is a device wherein holes and electrons respectively injected from a plurality of opposing electrodes are combined within a light-emitting layer that employs an organic substance, thereby generating an energy that excites a fluorescent substance within the light-emitting layer, causing the device to emit light. In an organic electroluminescent device of prior art, the electric field light emission efficiency rate with respect to added energy is about 20%.

On the other hand, in an organic EL display of prior art, the organic electroluminescent device exists in a form that employs a configuration wherein a plurality of organic EL units is provided between the anode and cathode thereof and a charge generating composite layer is provided between the plurality of organic EL units so as to improve contrast (refer to Paragraph [0039] of JP, A, 2006-73484). This charge generating composite layer is designed to improve efficiency so that the light emitted by one of the organic EL units arranged in multiple tiers does not affect the other organic EL units, for example.

Nevertheless, while the organic EL display of prior art modestly improves contrast by thus providing the charge generating composite layer between the plurality of organic EL units and ensuring that the light emitted by one organic EL unit does not affect the other organic EL units as described above, the problem arises that the amount of power consumption increases as a result of providing the plurality of EL units in the first place. Thus, the organic EL display of prior art is confronted with the difficulty of improving electroluminescent efficiency while suppressing power consumption.

The above-described problem is given as one example of the problems that are to be solved by the present invention.

### SUMMARY OF THE INVENTION

To solve the foregoing problem, the invention according to claim 1 is an organic electroluminescent device comprising: a plurality of electrodes stacked on a substrate, at least one of the electrodes being transparent or semi-transparent; an organic electroluminescent layer that is stacked between the plurality of electrodes and emits light by means of an electric field generated between the plurality of electrodes by an applied voltage; and a power generating semiconductor part that is arranged on the periphery of the organic electroluminescent layer, and utilizes an internal light among the light emitted by the organic electroluminescent layer in order to generate power by a photoelectric conversion function, the internal light not having been emitted from the transparent or semi-transparent electrode to the outside but remains inside.

To solve the foregoing problem, the invention according to claim 19 is a display device comprising: a display panel having an organic electroluminescent device; and a driving circuit, the organic electroluminescent device including: a plurality of electrodes stacked on a substrate, at least one of the electrodes being transparent or semi-transparent; an organic electroluminescent layer that is stacked between the plurality of electrodes and emits light by means of an electric field generated between the plurality of electrodes by an applied voltage, and a power generating semiconductor part that is arranged on the periphery of the organic electroluminescent layer, and utilizes an internal light among the light emitted by the organic electroluminescent layer in order to generate power by a photoelectric conversion function, the internal light not having been emitted from the transparent or semi-transparent electrode to the outside but remains inside; and the driving circuit providing an applied voltage between the plurality of electrodes in accordance with inputted image data so as to drive each of the organic electroluminescent devices of the display panel.

### BRIEF DESCRIPTION OF THE DRAWINGS

FIG. 1 is a front view illustrating an example of the outer appearance of the display device comprising the organic electroluminescent device of embodiment 1.

FIG. 2 is a partial cross-sectional view illustrating a configuration example of the organic electroluminescent device of embodiment 1.

FIG. 3 is a view illustrating an example of the refracted state of light when light passes through a plurality of layers.

FIG. 4 is a view illustrating an example of the refracted state of light when light passes through a plurality of layers.

FIG. 5 is a partial cross-sectional view illustrating a configuration example of the organic electroluminescent device of embodiment 2.

FIG. 6 is a partial cross-sectional view illustrating a configuration example of the organic electroluminescent device of embodiment 3.

### DETAILED DESCRIPTION OF THE PREFERRED EMBODIMENTS

The following describes an embodiment of the present invention with reference to accompanying drawings.

### Embodiment 1

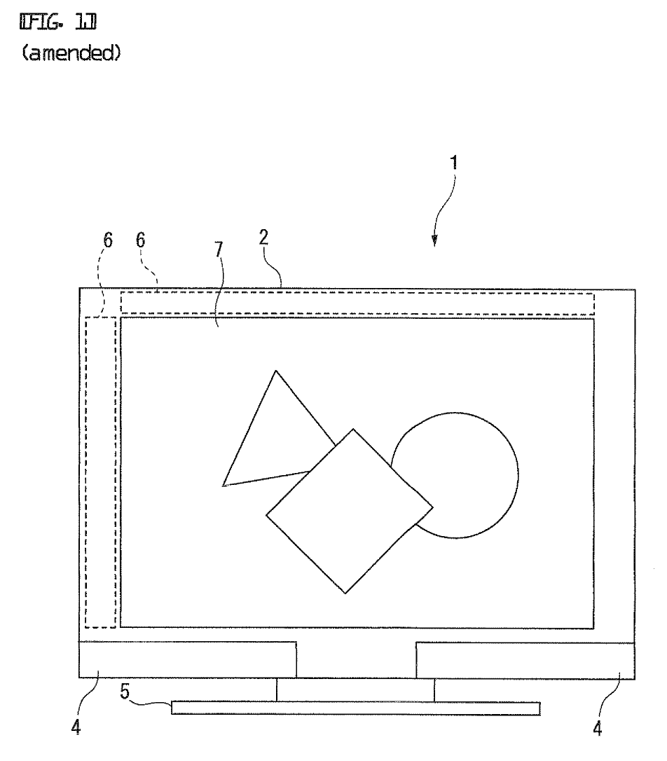

FIG. 1 is a front view illustrating an example of the outer appearance of a display device 1 comprising an organic electroluminescent device 3 of embodiment 1.

The display device 1 has a housing 2 and legs 5. The housing 2 is supported on an installation surface by the legs 5. This housing 2, based on its outer appearance, comprises a display panel 7 and two speakers 4. The display panel 7 is provided at the center of the housing 2 and, at this center of the housing 2, has a function of displaying images based on image data inputted from an external source. The speakers 4 are respectively provided on the right side and left side underneath the housing 2.

The speakers 4 have a function of outputting sound in synchronization with the image displayed on the display panel 7. The housing 2 comprises a driving circuit 6 within its interior. This driving circuit 6 performs drive control for displaying images based on the aforementioned image data on the display panel 7.

The display panel 7 is a panel that employs a so-called organic electroluminescent device (organic EL device). The display panel 7 comprises a configuration wherein a large number of organic electroluminescent devices are arranged in a matrix shape. These organic electroluminescent devices arranged in a matrix shape are driven and controlled per pixel based on the control performed by the driving circuit 6.

### Configuration Example of Organic Electroluminescent Device

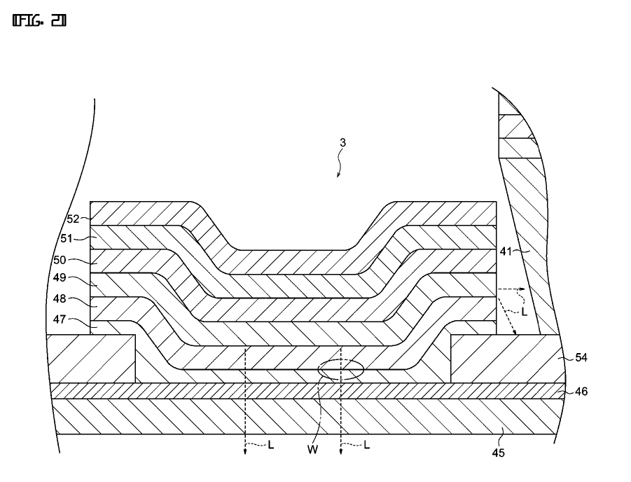

FIG. 2 is a cross-sectional view illustrating a configuration example of the organic electroluminescent device of the display panel 7 of FIG. 1, as enlarged.

The organic electroluminescent device 3 is a top-emission type organic electroluminescent device, for example, with one device formed correspondingly for each color red, green, and blue, for example. In the organic electroluminescent device 3, an anode 46 (transparent or semi-transparent electrode), a hole injection layer 47, a hole transport layer 48, a light-emitting layer 49 (organic electroluminescent layer), an electron transport layer 50, an electron injection layer 51, and a cathode 52 (electrode) are stacked in the described order on a glass substrate 45. Furthermore, the organic electroluminescent device 3 may employ a structure wherein an electric charge and exciter diffusion layer for capturing an electric charge and exciter within the light-emitting layer 49 is layered.

Excluding the light-emitting layer 49, these layers, i.e., the anode 46, the hole injection layer 47, the hole transport layer 48, the electron transport layer 50, the electron injection layer 51, and the cathode 52 (electrode), are each made of a material such as ITO (Indium Tin Oxide), CuPc, NPB, Alq₃, LiF, and Al, for example.

The organic electroluminescent device 3 shown in the figure corresponds to one pixel section. The organic electroluminescent device 3 is provided with a barrier 54 along the anode 46, between the neighboring organic electroluminescent device 3. This barrier 54 is an insulating body formed on the anode 46, and has the function of insulating the area between each organic electroluminescent device. On this barrier 54 remains a side section 41 formed when the organic electroluminescent device 3 is formed, for example. Note that this side section 41 may be intentionally formed rather than just a member that remains from the formation of the organic electroluminescent device 3.

The glass substrate 45 is formed using a transparent or semi-transparent material. Note that the anode 46 may be made of the material IZO rather than the above-mentioned ITO. The anode 46 comprises a transparent or semi-transparent electrode through which a light L emitted by the light-emitting layer 49 is transmitted, as described later. The anode 46 (one of the plurality of electrodes) is formed on the glass substrate 45 at large, along the glass substrate 45. This anode 46 has a function of supplying holes to the light-emitting layer 49 described later.

The hole injection layer 47 is stacked so that the holes are readily removable from the anode 46. The hole transport layer 48 has a function of transporting the holes removed from the anode 46 by the hole injection layer 47 to the light-emitting layer 49. The hole injection layer 47 is mainly stacked on the anode 46. The hole transport layer 48 is stacked on the hole injection layer 47.

The light-emitting layer 49 is a light-emitting device that employs a so-called electroluminescence (EL) phenomenon. The light-emitting layer 49 (power generating semiconductor part) is stacked between the plurality of electrodes 46 and 52, and has a function of emitting light by an electric field generated between the plurality of electrodes 46 and 52 by an applied voltage. This light-emitting layer 49 outputs its own light L by utilizing a phenomenon in which light is emitted based on energy received from an external source using an electric field.

In the organic electroluminescent device 3 of this embodiment, while the light-emitting layer 49 mainly emits the light L (external light) downward in the case of a top-emission type, in actuality the light-emitting layer 49 also emits the light L in unintended directions, such as shown on the right side in the example. The light L thus emitted in an unintended direction by the light-emitting layer 49 is not removed to an external source of the organic electroluminescent device 3 as external light, but rather is lost within the organic electroluminescent device 3. In this embodiment, the light from the light L thus emitted by the light-emitting layer 49 that cannot be removed as external light is referred to as “internal light.”

The electron transport layer 50 is stacked on the light-emitting layer 49. Furthermore, the electron injection layer 51 is stacked on the electron transport layer 50. The cathode 52 is formed on the electron injection layer 51. Of these, the electron injection layer 51 has a function of readily removing electrons from the cathode 52. Additionally, the electron transport layer 50 has a function of efficiently transporting the electrons removed from the cathode 52 by the electron injection layer 51 to the light-emitting layer 49.

### Configuration Example of Power Generating Semiconductor Part

In this embodiment, the organic electroluminescent device 3 is provided with a power generating semiconductor part. In the embodiment, this power generating semiconductor part is stacked as a layer between the aforementioned plurality of electrodes (the cathode 52 and the anode 46). Specifically, the power generating semiconductor part is the electron injection layer 51, the electron transport layer 50, the hole transport layer 48, or the hole injection layer 47, or any combination thereof formed between the plurality of electrodes (52 and 46).

The power generating semiconductor part is arranged on the periphery of the light-emitting layer 49 (organic electroluminescent device), and has a function of utilizing from the light L emitted by the light-emitting layer 49 the internal light that has not been emitted from the anode 46 (transparent or semi-transparent electrode) to the outside and remains inside, and generating power by a photoelectric conversion function. This power generating semiconductor part comprises an organic semiconductor layer or an inorganic semiconductor layer, for example.

In this embodiment, the power generating semiconductor part is stacked as at least either the hole injection layer 47 or the hole transport layer 48, for example, closer to the transparent or semi-transparent electrode (anode 46) than the light-emitting layer 49. Specifically, in this embodiment, the power generating semiconductor part is the hole injection layer 47 as an example, and the hole injection layer 47 is referred to as the “power generating semiconductor part 47” in the descriptions that follow.

The power generating semiconductor part 47 (photoelectric conversion film) is made of a material that absorbs the internal light L of a specific wavelength type as the wavelength type of the internal light L that should be absorbed. The power generating semiconductor part 47 must convert this light L to a charge upon absorption of the light L and is therefore preferably a film having a high level of light absorption (transmissivity), charge separation efficiency, and charge transport for the specific wavelength type. Here, “charge separation” refers to separation into holes and electrons within the power generating semiconductor part 47. With such a structure of the organic electroluminescent device 3 of this embodiment, holes are transported from the power generating semiconductor part 47 (hole injection layer) to the hole transport layer 48, and electrons are injected into the anode 46.

The power generating semiconductor part 47 is made of a material that absorbs the internal light L of the specific wavelength range. Specifically, it is best if the power generating semiconductor part 47 is made of a material having a large absorption range and high absorption rate (low transmissivity) at the specific wavelength range, that is, the wavelength band from the ultraviolet area to the infrared area (including visible light), for example.

The power generating semiconductor part 47 is formed into multiple layers corresponding to the colors of the internal light to be outputted by the light-emitting layer 49, between the plurality of electrodes (the cathode 52 and the anode 46). Possible materials employed as the material of this semiconductor unit 47 include a bipolar semiconductor material (a semiconductor material having both polarities, both holes and electrons).

### Examples of Power Generating Semiconductor Part Material

Specific materials that may be suitably selected for the power generating semiconductor part 47 also include, for example, a polyacene derivative (close to a p-type bipolar) such as pentacene or tetracene, a phthalocyanine derivative (p-type, also transports electrons if a thin film) of CuPc or ZnPc, thiophene and polythiophene derivatives (p-type material), a fullerene derivative (n-type) such as PCBM, a material (organic solar cell, organic photovoltaic device material) such as a periden derivative, a quinacridone derivative (p type), or an organic imaging device material such as a coumarin derivative (p-type). The material used for the organic electron donor constituting an organic electron donor layer (hereinafter sometimes referred to as “p-type layer” as well) 11 is not particularly limited as long as the charge carrier is a hole and the material exhibits p-type semiconductor characteristics.

Additional specific examples of the power generating semiconductor part 47 include a macromolecule such as an oligomer or polymer having thiophene and derivatives thereof in its backbone, an oligomer or polymer having phenylenevinylene and derivatives thereof in its backbone, an oligomer or polymer having vinylcarbazole and derivatives thereof in its backbone, an oligomer or polymer having pyrrole and derivatives thereof in its backbone, an oligomer or polymer having acetylene and derivatives thereof in its backbone, an oligomer or polymer having isothianaphthene and derivatives thereof in its backbone, or an oligomer or polymer having heptadiene and derivatives thereof in its backbone; a low molecular weight molecule such as metal-free phthalocyanine or metal phthalocynine and derivatives thereof, diamines or phenyldiamines and derivatives thereof, an acene such as pentacene and derivatives thereof, a metal-free porphyrin or metal porphyrin such as porphyrin, tetramethylporphyrin, tetraphenylporphyrin, diazotetrabenzporphyrin, monoazotetrabenzporphyrin, diazotetrabenzporphyrin, triatetrabenzporphyrin, octaethylporphyrin, octaalkylthioporphyrazine, octaalkylaminoporphyrazine, hemiporphyrazine, chlorophyll, and derivatives thereof; or a quinone pigment such as cyanine pigment, merocya, benzoquinone, or naphthoquinone.

The central metals of the metal phthalocyanine and metal porphyrin employed are each a metal, metallic oxide, or metallic halide such as magnesium, zinc, copper, silver, aluminum, silicon, titanium, vanadium, chrome, manganese, iron, cobalt, nickel, tin, platinum, or lead.

On the other hand, the electron donor constituting the electron acceptor layer (hereinafter sometimes referred to as “n-type layer” as well) is not particularly limited in this application as long as the charge carrier is an electron and the material exhibits n-type semiconductor characteristics.

Specifically, the organic electron acceptor employed may be a macromolecule such as an oligomer or polymer having pyridine and derivatives thereof in its backbone, an oligomer or polymer having quinoline and derivatives thereof in its backbone, a ladder polymer based on a benzophenanthroline and derivatives thereof, or cyanopolyphenylenevinylene; or a low molecular weight molecule such as a fluorinated metal-free phthalocyanine or fluorinated metal phthalocyanine and derivatives thereof, perylene and derivatives thereof, naphthalene derivatives, or bathocuproine and derivatives thereof. Other possibilities include a modified or unmodified fullerene or carbon nanotube.

Note that the power generating semiconductor part 47 may be a compound semiconductor or oxide semiconductor rather than an organic material. In such as case, the organic electroluminescent device 3, in addition to such a layered configuration, is preferably further provided with a layer for efficiently injecting and transporting a charge generated and produced by the power generating semiconductor part 47.

Note that the power generating semiconductor part 47 may comprise a structure that includes an n-type semiconductor layer and p-type semiconductor layer, for example. Then, the power generating semiconductor part 47 may be formed as a film using a vapor deposition, evaporation coating, or coating method, a sol-gel method, or a sputtering method.

### Operation Example of the Organic Electroluminescent Device 3

The organic electroluminescent device 3 and the display device 1 into which the organic electroluminescent device 3 is built thus comprise the above-described configuration, and an example of the operation of the organic electroluminescent device 3 and the display device 1 into which the organic electroluminescent device 3 is built will now be described.

In the display device 1 illustrated in FIG. 1, a large number of such the organic electroluminescent devices 3 are arranged in a matrix shape in the display panel 7 thereof, and the large number of organic electroluminescent devices 3 operate as described below based on the control performed by the driving circuit 6.

### General Operation Example of the Organic Electroluminescent Device 3

First, the driving circuit 6 drives each of the organic electroluminescent devices 3 based on inputted imaged data so as to display an image based on the image data on the display panel 7. Then, in each of the organic electroluminescent devices 3, this driving circuit 6 applies DC voltage from a predetermined power supply (not shown) between the anode 46 and the cathode 52 illustrated in FIG. 2.

When DC voltage is thus applied to the anode 46 and the cathode 52, the anode 46 discharges a greater number of holes due to the action of the hole injection layer 47. The holes discharged by the anode 46 arrive at the hole transport layer 48 via the hole injection layer 47. The hole transport layer 48 transports the holes to the light-emitting layer 49. In this manner, the light-emitting layer 49 is capable of receiving holes from the hole transport layer 48.

On the other hand, the cathode 52 injects electrons into the electron transport layer 50 by the action of the electron injection layer 51. The electron transport layer 50 transports the electrons to the light-emitting layer 49. In this manner, the light-emitting layer 49 is capable of receiving electrons discharged from the cathode via the electron injection layer 51 and the electron transport layer 50.

The light-emitting layer 49 operates as described below based on the holes and electrons thus injected. The injected holes and electrons are recombined inside the light-emitting layer 49, changing to an excited state, which is in an unstable, high-energy state. The light-emitting layer 49 then promptly returns to its original ground state, which is a stable, low-energy state. At this time, the light-emitting layer 49 emits the light L based on the difference in energy between the excited state and the ground state.

With this arrangement, the display device 1 illustrated in FIG. 1 emits the light L from the pixels corresponding to each of the organic electroluminescent devices 3 based on the control performed by the driving circuit 6, making it possible to display a predetermined image on the display panel 7. At this time, the display device 1 is capable of outputting sound from the speakers 4 in synchronization with the display of this image.

### Absorption of Internal Light by Power Generating Semiconductor Part

When the light-emitting layer 49 thus emits the light L, the light L emitted by the light-emitting layer 49 is not all emitted from the organic electroluminescent device 3 but rather is partially lost therein.

The cause of such a loss of the internal light L includes cases where the light L is refracted by the difference in the refractive indices (refractive index difference) of each layer between the anode 46 and the cathode 52, for example, which causes the leaked light L to be guided along the boundary direction of each layer. In this embodiment, the leaked light L thus guided along the boundary direction of each layer is referred to as “guided wave.” In the embodiment, the power generating semiconductor part 47 generates power by using such a guided wave of the leaked light L. The use of the leaked light L based on the refractive index difference of each layer 47, etc., by the power generating semiconductor part 47 will be described later.

The organic electroluminescent device 3 of this embodiment is characterized in that it comprises the plurality of electrodes 46 and 52 (anode, cathode) stacked on the substrate 45 (glass substrate), at least one of the electrodes 46 and 52 being transparent or semi-transparent, the organic electroluminescent layer 49 (light-emitting layer) that is stacked between the plurality of electrodes 46 and 52 and emits light by means of an electric field generated between the plurality of electrodes 46 and 52 by an applied voltage, and the power generating semiconductor part 47, 48, 50, or 51, or any combination thereof (a hole injection layer, hole transport layer, electron transport layer, or electron injection layer, or any combination thereof) that is arranged on the periphery of the organic electroluminescent layer 49 and utilizes the internal light among the light emitted by the organic electroluminescent layer 49 in order to generate power by a photoelectric conversion function, the internal light not having been emitted from the transparent or semi-transparent electrode 46 (anode) to the outside but rather remains on the inside.

The display device 1 of this embodiment is characterized in that it comprises the display panel 7 having the organic electroluminescent device 3 and the driving circuit 6, the organic electroluminescent device 3 including the plurality of electrodes 46 and 52 (anode, cathode) stacked on the substrate 45 (glass substrate), at least one of the electrodes 46 and 52 being transparent or semi-transparent, the organic electroluminescent layer 49 (light-emitting layer) that is stacked between the plurality of electrodes 46 and 52 and emits light by means of an electric field generated between the plurality of electrodes 46 and 52 by an applied voltage, and the power generating semiconductor part 47, 48, 50, or 51, or any combination thereof (hereinafter “power generating semiconductor part 47, etc.”) that is arranged on the periphery of the organic electroluminescent layer 49 and utilizes the internal light among the light emitted by the organic electroluminescent layer 49 in order to generate power by a photoelectric conversion function, the internal light not having been emitted from the transparent or semi-transparent electrode 46 (anode) to the outside but rather remains on the inside; and the driving circuit 6 providing an applied voltage between the plurality of electrodes 46 and 52 in accordance with inputted image data so as to drive each of the organic electroluminescent devices 3 of the display panel 7.

In this manner, in this embodiment the organic electroluminescent device 3 is also provided with a mechanism that automatically generates a charge internally. Specifically, the organic electroluminescent device 3 is provided with a photoelectric conversion function in the power generating semiconductor part 47, 48, 50, or 51, or any combination thereof, that exists in the interior thereof.

With this arrangement, the power generating semiconductor part 47, 48, 50, or 51, or any combination thereof (hereinafter referred to as “power generating semiconductor part 47, etc.”) is capable of absorbing the internal light generated by the organic electroluminescent device 3. Specifically, the power generating semiconductor part 47, etc., that absorbed this internal light generates excitons, and separates and transports these excitons into charges (holes and electrons) under a specific electric field. The separated and transported charges act with a charge supplied (injected) from an external source, causing the organic electroluminescent layer 49 to emit electroluminescence (EL).

Specifically, first the organic electroluminescent layer 49 (light-emitting layer) emits light by an electric field generated between the plurality of electrodes 46 and 52 by an applied voltage. A portion of the light L thus generated within the organic electroluminescent device 3 passes through the transparent or semi-transparent electrode 46 (anode) and is outputted to the outside, while the greater portion of the light L is light that has leaked and still remains within the organic electroluminescent device 3 (hereinafter referred to as “internal light” in this embodiment).

In the organic electroluminescent device 3, the power generating semiconductor part 47, etc., arranged on the periphery of the organic electroluminescent layer 49 (light-emitting layer) absorbs this internal light so as to generate excitons, separates the excitons into charges (holes and electrons), and transports the charges under a specific electric field. The power generating semiconductor part 47, etc., is capable of producing a new charge and generating power by such a photoelectric conversion action.

As a result, in the organic electroluminescent device 3, with the amount of charge thus separated and transported, the charge that is to be supplied (injected) from the outside is minimal Furthermore, this organic electroluminescent device 3 is capable of suppressing the voltage applied to the plurality of electrodes 46 and 52 and reducing internal power consumption by the charge thus newly generated.

Further, since the organic electroluminescent device 3 is capable of emitting the light L in an equivalent amount even when the amount of charge to be supplied (injected) from an outside source to (into) the organic electroluminescent layer 49 is minimized owing to the newly generated charge, electroluminescent efficiency is improved. This electroluminescent efficiency (cd/A) is expressed by electroluminescent brightness [cd]/current [A].

Specifically, in a case where the organic electroluminescent device 3 is a specific device having a charge emission efficiency of 10 cd/A, for example, when the power generating semiconductor part 47, etc., is provided and a 50% reduction in power consumption is achieved, the electroluminescent efficiency becomes 20 cd/A. Note that a reduction in the power consumption of the organic electroluminescent device 3 is possible due to the reduction in the injected amount of charge supplied from an external source.

The organic electroluminescent device 3 of the above embodiment is characterized in that the power generating semiconductor part 47, etc., is an organic semiconductor or inorganic semiconductor. The organic electroluminescent device 3 built into the display device 1 of the above embodiment is characterized in that the power generating semiconductor part 47, etc., is an organic semiconductor or inorganic semiconductor.

According to such a configuration, the organic electroluminescent device 3 is capable of having the charge injection layer 51, which is an organic semiconductor or inorganic semiconductor, built therein as the power generating semiconductor part, making it possible to no longer separately provide this power generating semiconductor part and the charge injection layer 51, etc., thereby minimizing size.

The organic electroluminescent device 3 of the above embodiment is characterized in that the power generating semiconductor part 47, etc., is stacked as a layer between the plurality of electrodes 46 and 52. The organic electroluminescent device 3 built into the display device 1 of the above embodiment in characterized in that the power generating semiconductor part 47, etc., is stacked as a layer between the plurality of electrodes 46 and 52.

The power generating semiconductor part 47, etc., is stacked between the plurality of electrodes 46 and 52 along with the organic electroluminescent layer 49, thereby enabling receipt of the light emitted by the organic electroluminescent layer 49 across a wide area. As a result, the power generating semiconductor part 47, etc., can efficiently perform photoelectric conversion, reduce the power consumption inside the organic electroluminescent device 3, and improve the electroluminescent efficiency of the organic electroluminescent layer 49.

The organic electroluminescent device 3 of the above embodiment is characterized in that the power generating semiconductor part is the electron injection layer 51, or the electron transport layer 50, or the hole transport layer 48, or the hole injection layer 47, or a combination of at least one of the electron injection layer 51, the electron transport layer 50, the hole transport layer 48, and the hole injection layer 47, respectively formed between the plurality of electrodes 46 and 52.

The organic electroluminescent device 3 built into the display device 1 of the above embodiment is characterized in that the power generating semiconductor part is the electron injection layer 51, or the electron transport layer 50, or the hole transport layer 48, or the hole injection layer 47, or a combination of at least one of the electron injection layer 51, the electron transport layer 50, the hole transport layer 48, and the hole injection layer 47, respectively formed between the plurality of electrodes 46 and 52.

With this arrangement, even without a separate power generating semiconductor part between the plurality of electrodes 46 and 52, the power generating semiconductor part 47, etc., may be built within the organic electroluminescent device 3, thereby making it possible to provide such the power generating semiconductor part 47, etc., without an increase in size.

The organic electroluminescent device 3 of the above embodiment is characterized in that the power generating semiconductor part 47, etc., is formed in multiple layers respectively corresponding to the colors of the internal light L, between the plurality of electrodes 46 and 52.

The organic electroluminescent device 3 built into the display device 1 of the above embodiment is characterized in that the power generating semiconductor part 47, etc., is formed in multiple layers respectively corresponding to the colors of the internal light L, between the plurality of electrodes 46 and 52.

According to this configuration, each of the multi-layered power generating semiconductor parts 47, etc., is capable of absorbing the internal light L on a per color basis, for example, making it possible to more efficiently utilize the internal light L to generate power.

The organic electroluminescent device 3 of the above embodiment is characterized in that the power generating semiconductor part 47, etc., is made of a material that absorbs the internal light L of a specific wavelength range.

The organic electroluminescent device 3 built into the display device 1 of the above embodiment is characterized in that the power generating semiconductor part 47, etc., is made of a material that absorbs the internal light L of a specific wavelength range.

With the above organic electroluminescent device 3, it is possible to exhibit the following effect when the power generating semiconductor part 47, etc., is adjusted so as to increase the light absorption efficiency (low transmissivity) of the specific wavelength range. That is, the power generating semiconductor part 47, etc., is capable of not only efficiently absorbing internal light to generate power as described above, but also improving the contrast of the light L of other wavelength ranges due to absorption of the specific wavelength range.

The organic electroluminescent device 3 of the above embodiment is characterized in that the power generating semiconductor part 47, etc., is made of a material that absorbs the internal light L from the ultraviolet area to the infrared area as the specific wavelength range.

The organic electroluminescent device 3 built into the display device 1 of the above embodiment is characterized in that the power generating semiconductor part 47, etc., is made of a material that absorbs the internal light L from the ultraviolet area to the infrared area as the specific wavelength range.

According to such a configuration, the organic electroluminescent device 3 is used in the display device 1, for example, and therefore absorbs from the light L outputted by the organic electroluminescent layer 49 the internal light L, from the ultraviolet wavelength to the infrared wavelength, making it possible to reduce the internal light L that is scattered internally and improve the contrast based on the external light L.

The organic electroluminescent device 3 of the above embodiment is characterized in that the power generating semiconductor part 47, etc., is a film having a high charge separation efficiency and charge transport level.

The organic electroluminescent device 3 built into the display device 1 of the above embodiment is characterized in that the power generating semiconductor part 47, etc., is a film having a high charge separation efficiency and charge transport level.

With such a configuration, the power generating semiconductor part 47, etc., of the organic electroluminescent device 3 more efficiently generates a charge based on the internal light L, making it possible to efficiently supply (inject) the generated charge to (into) the organic electroluminescent layer 49 (light-emitting layer). As a result, the organic electroluminescent layer 49 further suppresses power consumption, thereby further improving the electroluminescent efficiency.

The organic electroluminescent device 3 of the above embodiment is characterized in that the power generating semiconductor part 47, etc., is made of a bipolar semiconductor material. The organic electroluminescent device 3 built into the display device 1 of the above embodiment is characterized in that the power generating semiconductor part 47, etc., is made of a bipolar semiconductor material.

With such a configuration, the layering employing the bipolar semiconductor material is easy, making it possible to simply form the power generating semiconductor part 47, etc.

The organic electroluminescent device 3 of the above embodiment is characterized in that the power generating semiconductor part 47, etc., is formed using one of a vapor deposition, evaporation coating, or coating method, a gel-sol method, sputtering method, and the like. The organic electroluminescent device 3 built into the display device 1 of the above embodiment is characterized in that the power generating semiconductor part 47, etc., is formed using one of a vapor deposition, evaporation deposition, coating method, a gel-sol method, sputtering method, and the like. With this arrangement, the power generating semiconductor part 47, etc., can be simply stacked using a general film formation technique.

### Example of a Power Generation Method Utilizing the Refractive Index Difference of Each Layer

In such the organic electroluminescent device 3, the external light L that is to be outputted to the outside via the glass substrate 45 from the light L outputted by the light-emitting layer 49 amounts to approximately 20% of the light L outputted by the light-emitting layer 49. The remaining light is the internal light L lost as a result of the loss within the organic electroluminescent device 3. Such lost light is considered to be lost mainly when waves are guided in the horizontal direction through the boundary of each layer when the light passes through the boundary of each layer. More specifically, the events related to the loss of this light are as follows.

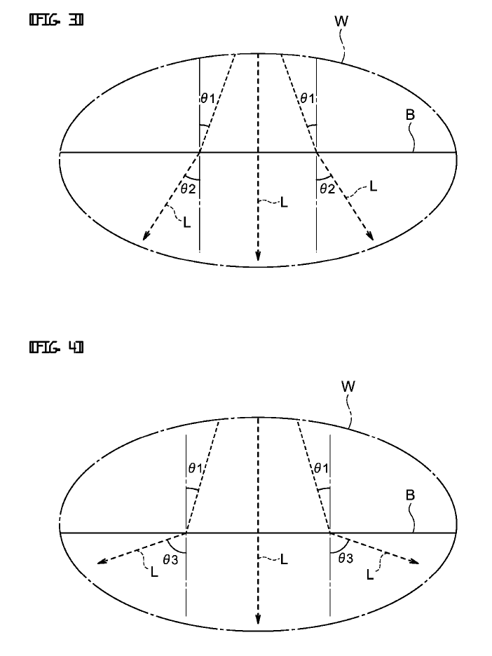

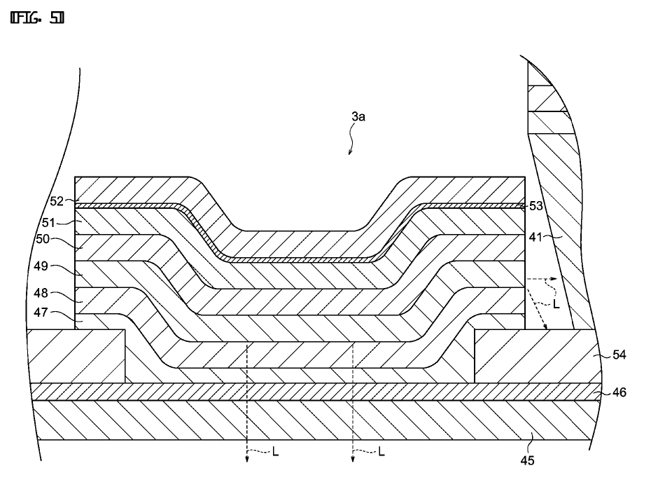

FIG. 3 and FIG. 4 are cross-sectional views each illustrating an example of a mode where the light L is refracted based on the refractive index difference of each layer. Note that in FIG. 3 and FIG. 4, the light L passes from the upper-side layer to the lower-side layer.

The example shown in FIG. 3 illustrates an example of a case where the refractive index difference of both layers is relatively small. In this case, the angle of incidence of the layer closer to where the light L enters is θ1, and the output angle in the layer closer to where the light L is emitted is θ2. In the example in the figure, the light L guided at the boundary B of each layer is understood to be minimal

The example shown in FIG. 4 illustrates an example of a case where the refractive index difference of both layers is large. In this case, the angle of incidence of the layer closer to where the light L enters is θ1 as in the case of FIG. 3, and the output angle in the layer closer to where the light L is emitted is θ3. In the example in the figure, the amount of light L guided at the boundary B of each layer is understood to be large.

As described above, the case of a large refractive index difference between both layers results in a greater amount of guided waves of light (leaked light) in the direction along the boundary B of each layer. Here, the power generating semiconductor 47 of the embodiment preferably generates power utilizing such a guided wave of the light L of the boundary B of each layer.

Here, in the embodiment, the above-described power generating semiconductor part 47 is preferably stacked so as to increase the refractive index difference. Normally, the refractive index of the anode 46 is approximately 2.0, and the refractive index of the light-emitting layer 49 is approximately 1.6 to 1.8. The refractive index of the glass substrate 45 is approximately 1.5. Thus, the power generating semiconductor part 47 may be provided as the hole injection layer 47, the hole transport layer 48, the electron transport layer 50, or the electron injection layer 51, or any combination thereof, for example, so as to increase the refractive index difference between each of these layers.

Here, the organic electroluminescent device 3 of the above embodiment is characterized in that the power generating semiconductor part 47 is made of such material that a difference of the refractive index of the material and the refractive index of the one of the aforementioned layers 48 and the like neighboring on the side where the internal light L enters is a predetermined value or higher.

The organic electroluminescent device 3 built into the display device 1 of the above embodiment is characterized in that the power generating semiconductor part is made of such material that a difference of the refractive index of the material and the refractive index of the one of the aforementioned layers 48 and the like neighboring on the side where the internal light L enters is a predetermined value or higher.

First, in a case where the light passes through a plurality of neighboring layers, a higher difference in the refractive index (refractive index difference) of the plurality of layers results in greater amount of refraction and, in turn, a greater amount of waves guided in the direction along the boundary of the plurality of layers. The internal light L that enters from the neighboring layer 48, etc., having a sufficiently high refractive index difference with the power generating semiconductor part 47, etc., passes across a longer distance than when not largely refracted within the power generating semiconductor part 47, etc. This makes it possible for the power generating semiconductor part 47, etc., to absorb a greater amount of internal light L than in a case where the light passes without largely being refracted as described above, and then generate and separate excitons into charges, and transport the separated excitons under a specific electric field. That is, the power generating semiconductor part 47, etc., is capable of producing a new charge and generating power by such photoelectric conversion action.

With this arrangement, in the organic electroluminescent device 3, with the amount of charge thus separated and transported, the charge that is to be supplied (injected) from the outside is minimal. Furthermore, this organic electroluminescent device 3 is capable of suppressing the voltage applied to the plurality of electrodes 46 and 52 and reducing internal power consumption by the charge thus newly generated.

Further, since the organic electroluminescent device 3 is capable of emitting the light L in an equivalent amount even when the amount of charge to be supplied (injected) from an outside source to (into) the organic electroluminescent layer 49 is minimized owing to the newly generated charge, electroluminescent efficiency is improved.

Furthermore, the organic electroluminescent device 3 of the above embodiment is characterized in that at least one of the power generating semiconductor parts 47 or 48 is stacked closer to the transparent or semi-transparent electrode 46 (anode) than the organic electroluminescent layer 49.

Further, the organic electroluminescent device 3 built into the display device 1 of the above embodiment is characterized in that at least one of the power generating semiconductor parts 47 or 48 is stacked closer to the transparent or semi-transparent electrode 46 (anode) than the organic electroluminescent layer 49.

The light L emitted by the organic electroluminescent layer 49 is refracted at the boundary of each layer of the organic electroluminescent layer 49, the hole injection layer 47, the hole transport layer 48, the anode 46, and the glass substrate 45 when passing through the hole injection layer 47 and the hole transport layer 48 stacked between the organic electroluminescent layer 49 and the anode 46 when outputted to the outside, and as a result is internally lost in part and not completely emitted to the outside.

This power generating semiconductor part absorbs the light L thus lost between the organic electroluminescent layer 49 and the glass substrate 45, making it possible to produce a new charge and generate power. That is, the power generating semiconductor part is capable of generating power by utilizing from the light L that is to be emitted to the outside as external light the internal light L that cannot be utilized as the external light L due to the difference in the refractive index between each layer.

With this arrangement, in the organic electroluminescent device 3, with the amount of charge thus separated and transported, the charge that is to be supplied (injected) from the outside is minimal. Furthermore, this organic electroluminescent device 3 is capable of suppressing the voltage applied to the plurality of electrodes 46 and 52 and reducing internal power consumption by the charge thus newly generated.

Further, since the organic electroluminescent device 3 is capable of emitting the light L in an equivalent amount even when the amount of charge to be supplied (injected) from an outside source to (into) the organic electroluminescent layer 49 is minimized owing to the newly generated charge, electroluminescent efficiency is improved.

Furthermore, due to the decrease in the internal light L subjected to diffused reflection between the organic electroluminescent layer 49 and the glass substrate 45, the organic electroluminescent device 3 is capable of outputting a clear external light L, thereby improving contrast.

### Embodiment 2

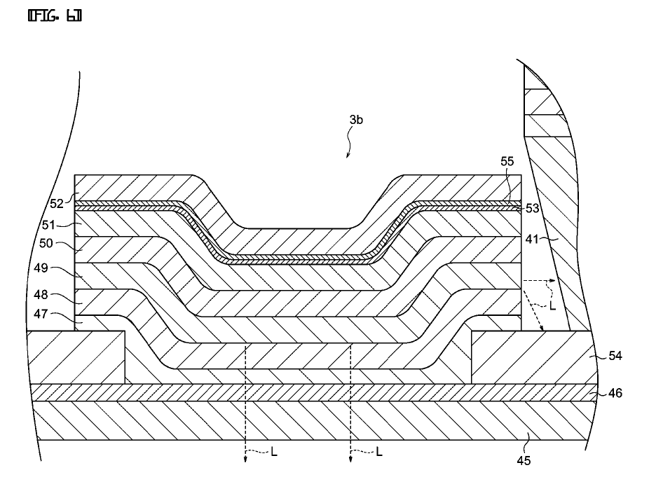

FIG. 5 is a partial cross-sectional view illustrating a configuration example of an organic electroluminescent device 3a of embodiment 2.

The organic electroluminescent device 3a of embodiment 2 has substantially the same configuration and operates substantially in the same manner as in embodiment 1. The same reference numerals as those employed in FIG. 1 to FIG. 4 of embodiment 1 will therefore be used for the same components and operations, and descriptions thereof will be omitted. The following will describe the organic electroluminescent device 3a with a focus on unique points.

While embodiment 1 has described an illustrative scenario in which a layer (the hole injection layer 47, the hole transport layer 48, the electron transport layer 50, the electron injection layer 51, or any combination thereof, for example) between the cathode 52 and the anode 46 functions as the power generating semiconductor part, embodiment 2 differs in that a power generating semiconductor part 53 is stacked separately from each of these layers 47, etc. Note that this power generating semiconductor part 53 has substantially the same function as the power generating semiconductor part 47, etc., of the aforementioned embodiment 1, excluding the point that the power generating semiconductor part 53 is stacked separately from each of these layers 47, etc., and the points described below.

The power generating semiconductor part 53 may be stacked in any position as long as that position is at least either anywhere between the anode 46, the hole injection layer 47, the hole transport layer 58, and the organic electroluminescent layer 49, or anywhere between the cathode 52, the electron injection layer 51, the electron transport layer 50, and the organic electroluminescent layer 49.

In embodiment 2, the power generating semiconductor part 53 is stacked between the cathode 52 and the electron injection layer 51 as an example. That is, with such a configuration, the organic electroluminescent device 3a is stacked in the order of the anode 46, the hole injection layer 47, the hole transport layer 48, the light-emitting layer 49, the electron transport layer 50, the electron injection layer 51, the power generating semiconductor part (photoelectric conversion layer) 53, and the cathode 52, from the glass substrate 45.

Possible stacked configurations used as the stacked configuration of the organic electroluminescent device 3a between the anode 46 and the cathode 52, starting from the side closer to the glass substrate 45, include that described below. Note that in the descriptions that follow a slash (“/”) is used to express the boundary between each layer.

Anode 46/hole injection layer 47/hole transport layer 48/light-emitting layer 49/electron transporting layer 50/electron injection layer 51/power generating semiconductor part 53/cathode 52.

### Embodiment 3

FIG. 6 is a partial cross-sectional view illustrated a configuration example of an organic electroluminescent device 3b of embodiment 3.

The organic electroluminescent device 3b of embodiment 3 has substantially the same configuration and operates substantially in the same manner as in embodiment 2. The same reference numerals as those employed in FIG. 1 to FIG. 5 of embodiment 2 will therefore be used for the same components and operations, and descriptions thereof will be omitted. The following will describe the organic electroluminescent device 3b with a focus on unique points.

The organic electroluminescent device 3b of embodiment 3 differs from the configuration of the organic electroluminescent device 3a of embodiment 2 in that it further comprises a buffer layer 55. This buffer layer 55 has the function of increasing the electron or hole injection efficiency into each neighboring layer. This buffer layer 55 may be stacked in at least one location between any combination of layers of the layers stacked between the cathode 52 and the anode 46.

In embodiment 3, the buffer layer 55 is formed between the cathode 52 and the power generating semiconductor part 53 as an example. That is, with such a configuration, the organic electroluminescent device 3b is stacked in the order of the anode 46, the hole injection layer 47, the hole transport layer 48, the light-emitting layer 49, the electron transport layer 50, the electron injection layer 51, the power generating semiconductor part 53, the buffer layer 55, and the cathode 52, from the glass substrate 45.

### Other Stacking Examples

The organic electroluminescent device 3b of embodiment 3 may also comprise a stacked configuration such as the following, from the glass substrate 45.

Anode 46/buffer layer 55/power generating semiconductor layer 53 (photoelectric conversion layer)/hole injection layer 47/hole transport layer 48/light-emitting layer 49/electron transport layer 50/electron injection layer 51/cathode 52.

The organic electroluminescent device 3b of embodiment 3 may also utilize a reverse stacked configuration such as the following, from the glass substrate 45.

Cathode 52/power generating semiconductor part 53/electron injection layer 51/electron transport layer 50/light-emitting layer 49/hole transport layer 48/hole injection layer 47/buffer layer 55/anode 46.

The organic electroluminescent device 3b of embodiment 3 is characterized in that it further comprises the buffer layer 55 that promotes the injection of a charge to the power generating semiconductor part 53, between at least one of the plurality of electrodes 46 and 52 (anode, cathode) and the power generating semiconductor part 53.

The organic electroluminescent device 3b built into the display device 1 of embodiment 3 is characterized in that it further comprises the buffer layer 55 that promotes the injection of a charge to the power generating semiconductor part 53, between at least one of the plurality of electrodes 46 and 52 (anode, cathode) and the power generating semiconductor part 53.

According to such a configuration, the power generating semiconductor part 53 is capable of readily accepting the charge of at least one of the plurality of electrodes 46 and 52 due to the existence of the buffer layer 55, thereby improving electroluminescent efficiency.

Note that the buffer layer 55 is preferably stacked near the power generating semiconductor layer 53. With this arrangement, when the buffer layer 55 is arranged near the power generating semiconductor part 53, a greater charge can be injected into the power generating semiconductor part 53. As a result, the power generating semiconductor part 53 is capable of more efficiently producing a new charge based on the absorbed internal light L and generating power.

### Embodiment 4

The organic electroluminescent device of embodiment 4 has substantially the same configuration and operates substantially in the same manner as in embodiments 1 to 3. The same reference numerals as those employed in FIG. 1 to FIG. 6 of embodiment 1 to embodiment 3 will therefore be used for the same components and operations, and descriptions thereof will be omitted. The following will describe the organic electroluminescent device with a focus on unique points.

While the aforementioned embodiment 1 to embodiment 3 has described an illustrative scenario in which the organic electroluminescent devices 3, 3a, and 3b each mainly comprise one layer of the power generating semiconductor part 53, the organic electroluminescent device of embodiment 4 may comprise a plurality of the power generating semiconductor parts 53.

According to such a stacked configuration, the organic electroluminescent device of embodiment 4 may utilize one of the following stacked configurations between the anode 46 and the cathode 52, from the glass substrate 45.

Anode 46/power generating semiconductor part 53 (photoelectric conversion layer)/hole injection layer 47/hole transport layer 48/light-emitting layer 49/electron transport layer 50/electron injection layer 51/power generating semiconductor layer 53 (photoelectric conversion layer)/cathode 52.

Anode 46/buffer layer 55/power generating semiconductor part 53 (photoelectric conversion layer)/hole injection layer 47/hole transport layer 48/light-emitting layer 49/electron transport layer 50/electron injection layer 51/power generating semiconductor part 53 (photoelectric conversion layer)/cathode 52.

Anode 46/power generating semiconductor part 53 (photoelectric conversion layer)/hole injection layer 47/hole transport layer 48/light-emitting layer 49/electron transport layer 50/electron injection layer 51/power generating semiconductor part 53 (photoelectric conversion layer)/buffer layer 55/cathode 52.

Anode 46/buffer layer 55/power generating semiconductor part 53 (photoelectric conversion layer)/hole injection layer 47/hole transport layer 48/light-emitting layer 49/electron transport layer 50/electron injection layer 51/power generating semiconductor part 53 (photoelectric conversion layer)/buffer layer 55/cathode 52.

According to embodiment 4, in addition to having the effects of any one of the embodiments 1 to 3, the organic electroluminescent device of the embodiment further comprises the plurality of power generating semiconductor parts 53, which further absorbs a greater amount of internal light L so as to generate a greater charge, thereby improving its electroluminescent efficiency.

### Modifications

Note that the embodiments of the present invention are not limited to the above, and various modifications are possible. In the following, details of such modifications will be described one by one.

### Power Generating Device

While each of the above embodiments has described an illustrative scenario of the organic electroluminescent devices 3, 3a, 3b, etc., comprising such a built-in power generating semiconductor part 47, etc., the present invention is not limited thereto, allowing the organic electroluminescent device 3 of embodiment 1, the organic electroluminescent device 3a of embodiment 2, the organic electroluminescent device 3b of embodiment 3, and the organic electroluminescent device of embodiment 4 (hereinafter “organic electroluminescent devices 3, 3a, 3b, etc.) each to be understood as follows.

That is, while these organic electroluminescent devices 3, 3a, 3b, etc., for example, are understood from the viewpoint of separately providing a special power generating function in addition to the light-emitting function from the light-emitting layer 49 in each of the embodiments, these devices can also be understood from the viewpoint of the power generating device separately comprising a light-emitting function from the light-emitting layer 49 in addition to the power generating function from the power generating semiconductor parts 47, 53, etc. That is, it is possible to change to a viewpoint of a configuration wherein the power generating device is provided with a light-emitting function of the light L from the light-emitting layer 49. That is, the power generating device here comprises the same configuration as the organic electroluminescent devices 3, 3a, 3b, etc., of each of the aforementioned embodiments.

According to such a power generating device, there is no need to separately incorporate a solar cell with the organic electroluminescent device 3, etc., within the display panel 7, thereby making it possible to stack the organic electroluminescent device 3, etc., of the aforementioned embodiments into a thin film so as to create a compact configuration and reduce manufacturing costs. Note that the power generating device may be arranged in any location associated with light loss from the guided waves of the internal light L, within the organic electroluminescent device 3, etc.

The power generating device of the above embodiment is a power generating device built into the organic electroluminescent device 3, etc., characterized in that it comprises the plurality of electrodes 46 and 52 (anode, cathode) stacked on the substrate 45 (glass substrate), at least one of the electrodes 46 and 52 being transparent or semi-transparent, the organic electroluminescent layer 49 (light-emitting layer) that is stacked between the plurality of electrodes 46 and 52 and emits light by means of an electric field generated between the plurality of electrodes 46 and 52 by an applied voltage, and the power generating semiconductor part 47, 48, 50, or 51, or any combination thereof, that is arranged on the periphery of the organic electroluminescent layer 49, utilizes the internal light among the light emitted by the organic electroluminescent layer 49 in order to generate power by a photoelectric conversion function, the internal light not having been emitted from the transparent or semi-transparent electrode 46 (anode) to the outside but rather remains inside.

In this manner, in this embodiment, the organic electroluminescent device 3 is also provided with a mechanism that automatically generates a charge internally. Specifically, the organic electroluminescent device 3 is provided with a photoelectric conversion function in the power generating semiconductor part 47, 48, 50, or 51 or any combination thereof (the hole injection layer, hole transport layer, electron transport layer, or electron injection layer, or any combination thereof) that exists in its interior.

With this arrangement, the power generating semiconductor part 47, 48, 50, or 51, or any combination thereof (hereinafter referred to as “power generating semiconductor part 47, etc.”) is capable of absorbing the internal light generated by the organic electroluminescent device 3. Specifically, the power generating semiconductor part 47, etc., that absorbed this internal light generates excitons, separates the excitons into charges (holes and electrons), and transports the separated excitons under a specific electric field. The separated and transported charges act with a charge supplied (injected) from an external source, causing the organic electroluminescent layer 49 to emit electroluminescence (EL).

Specifically, first the organic electroluminescent layer 49 (light-emitting layer) emits light by an electric field generated between the plurality of electrodes 46 and 52 by an applied voltage. The light L thus generated within the organic electroluminescent device 3 is partially outputted to the outside after passing through the transparent or semi-transparent electrode 46 (anode), while a large portion thereof remains as the internal light L.

In the organic electroluminescent device 3, the power generating semiconductor part 47, etc., arranged on the periphery of the organic electroluminescent layer 49 (light-emitting layer) absorbs this internal light so as to generate excitons, separates the excitons into charges (holes and electrons), and transports the separated excitons under a specific electric field. The power generating semiconductor part 47, etc., is capable of producing a new charge and generating power by such a photoelectric conversion action.

As a result, in the organic electroluminescent device 3, with the amount of charge thus separated and transported, the charge that is to be supplied (injected) from the outside is minimal Furthermore, this organic electroluminescent device 3 is capable of suppressing the voltage applied to the plurality of electrodes 46 and 52 and reducing internal power consumption by the charge thus newly generated.

Further, since the organic electroluminescent device 3 is capable of emitting the light L in an equivalent amount even when the amount of charge to be supplied (injected) from an outside source to (into) the organic electroluminescent layer 49 is minimized owing to the newly generated charge, electroluminescent efficiency is improved.

Specifically, in a case where the organic electroluminescent device 3 is a specific device having a charge emission efficiency of 10 cd/A, for example, when the power generating semiconductor part 47, etc., is provided and a 50% reduction in power consumption is achieved, the electroluminescent efficiency becomes 20 cd/A. This organic electroluminescent device 3 achieves a reduction in the injected amount of charge supplied from an external source, thereby making it possible to reduce power consumption.

The organic electroluminescent device 3, etc., having a built-in power generating device of the above embodiment is characterized in that the power generating semiconductor part 47, etc., is an organic semiconductor or inorganic semiconductor.

According to such a configuration, the organic electroluminescent device 3 is capable of having the charge injection layer 51, etc., which is an organic semiconductor or inorganic semiconductor, built therein as the power generating semiconductor part, making it possible to no longer separately provide this power generating semiconductor part and the charge injection layer 51, etc., thereby minimizing size.

The organic electroluminescent device 3, etc., having the built-in power generating device of the above embodiment is characterized in the power generating semiconductor part 47, etc., is stacked as a layer between the plurality of electrodes 46 and 52.

With the power generating semiconductor part stacked between the plurality of electrodes 46 and 52 along with the organic electroluminescent layer 49, it is possible to receive the light emitted by the organic electroluminescent layer 49 across a wide area. As a result, the power generating semiconductor part 47, etc., can efficiently perform photoelectric conversion, reduce the power consumption within the organic electroluminescent device 3, and improve the electroluminescent efficiency of the organic electroluminescent layer 49.

The organic electroluminescent device 3 having the built-in power generating device of the above embodiment is characterized in that the power generating semiconductor part is the electron injection layer 51, or the electron transport layer 50, or the hole transport layer 48, or the hole injection layer 47, or a combination of at least one of the electron injection layer 51, the electron transport layer 50, the hole transport layer 48, and the hole injection layer 47, respectively formed between the plurality of electrodes 46 and 52.

With this arrangement, even without a separate power generating semiconductor part between the plurality of electrodes 46 and 52, the power generating semiconductor part 47, etc., may be built within the organic electroluminescent device 3, thereby making it possible to provide such the power generating semiconductor part 47, etc., without an increase in size.

The organic electroluminescent device 3, etc., having the built-in power generating device of the above embodiment is characterized in that the power generating semiconductor part 47, etc., is made of such material that a difference of the refractive index of the material and the refractive index of the one of the aforementioned layers 47 and the like neighboring on the side where the internal light L enters is a predetermined value or higher.

First, in a case where the light passes through a plurality of neighboring layers, a higher difference in the refractive index (refractive index difference) of the plurality of layers results in greater amount of refraction and, in turn, a greater amount of waves guided in the direction along the boundary of the plurality of layers. The power generating semiconductor part 47, etc., has a sufficiently high refractive index difference with the neighboring layer 48, etc., causing the internal light that enters from that neighboring layer 48, etc., to pass across a longer distance than when not largely refracted within the power generating semiconductor part 47, etc. This makes it possible for the power generating semiconductor part 47, etc., to absorb a greater amount of internal light L than in a case where the light passes without largely being refracted as described above, and then generate and separate excitons into charges, and transport the separated excitons under a specific electric field. That is, the power generating semiconductor part 47, etc., is capable of producing a new charge and generating power by such photoelectric conversion action.

With this arrangement, in the organic electroluminescent device 3, with the amount of charge thus separated and transported, the charge that is to be supplied (injected) from the outside is minimal. Furthermore, this organic electroluminescent device 3 is capable of suppressing the voltage applied to the plurality of electrodes 46 and 52 and reducing internal power consumption by the charge thus newly generated.

Further, since the organic electroluminescent device 3 is capable of emitting the light L in an equivalent amount even when the amount of charge to be supplied (injected) from an outside source to (into) the organic electroluminescent layer 49 is minimized owing to the newly generated charge, electroluminescent efficiency is improved.

The organic electroluminescent device 3, etc., having the built-in power generating device of the above embodiment is characterized in that the power generating semiconductor part 47, etc., is stacked closer to the transparent or semi-transparent electrode 46 (anode) than the organic electroluminescent layer 49.

The light L emitted by the organic electroluminescent layer 49 is refracted at the boundary B of each layer of the organic electroluminescent layer 49, the hole injection layer 47, the hole transport layer 48, the anode 46, and the glass substrate 45 when passing through the hole injection layer 47 and the hole transport layer 48 stacked between the organic electroluminescent layer 49 and the anode 46 when outputted to the outside, and as a result is internally lost in part and not completely emitted to the outside.

This power generating semiconductor part 47, etc., thus absorbs the light originally lost between the organic electroluminescent layer 49 and the glass substrate 45, making it possible to produce a new charge and generate power. That is, the power generating semiconductor part 47, etc., is capable of generating power by utilizing from the light to be emitted to the outside as external light the internal light that cannot be utilized as external light due to the difference in the refractive index between each layer.

With this arrangement, in the organic electroluminescent device 3, with the amount of charge thus separated and transported, the charge that is to be supplied (injected) from the outside is minimal. Furthermore, this organic electroluminescent device 3 is capable of suppressing the voltage applied to the plurality of electrodes 46 and 52 and reducing internal power consumption by the charge thus newly generated.

Further, since the organic electroluminescent device 3 is capable of emitting the light L in an equivalent amount even when the amount of charge to be supplied (injected) from an outside source to (into) the organic electroluminescent layer 49 is minimized owing to the newly generated charge, electroluminescent efficiency is improved.

Furthermore, due to the decrease in the internal light L subjected to diffused reflection between the organic electroluminescent layer 49 and the glass substrate 45, the organic electroluminescent device 3 is capable of outputting a clear external light, thereby improving contrast.

The organic electroluminescent device 3, etc., having the built-in power generating device of the above embodiment is characterized in that the power generating semiconductor part 47, etc., is formed in multiple layers respectively corresponding to the colors of the internal light L, between the plurality of electrodes 46 and 52.

According to this configuration, the multi-layered power generating semiconductor part 47, etc., is capable of absorbing the internal light L on a per color basis, for example, making it possible to more efficiently utilize the internal light L to generate power.

The organic electroluminescent device 3, etc., having the built-in power generating device of the above embodiment is characterized in that the power generating semiconductor part 47, etc., is made of a material that absorbs the internal light L of a specific wavelength range.

With the above organic electroluminescent device 3, it is possible to exhibit the following effect when the power generating semiconductor part 47, etc., is adjusted so as to increase the light absorption efficiency (low transmissivity) of the specific wavelength range. That is, the power generating semiconductor part 47, etc., is capable of not only efficiently absorbing the internal light L as described above, but also improving the contrast of the light L of other wavelength ranges due to absorption of the specific wavelength range.

The organic electroluminescent device 3, etc., having the built-in power generating device of the above embodiment is characterized in that the power generating semiconductor part 47, etc., is made of a material that absorbs the internal light L from the infrared area to the ultraviolet area as the specific wavelength range.

According to such a configuration, the organic electroluminescent device 3 is used in the display device 1, for example, and therefore absorbs from the light L outputted by the organic electroluminescent layer 49 the internal light L, from the ultraviolet wavelength to the infrared wavelength, making it possible to reduce the internal light L that is scattered internally and improve the contrast based on the external light L.

The organic electroluminescent device 3, etc., having the built-in power generating device of the above embodiment is characterized in that the power generating semiconductor part 47, etc., is a film having a high charge separation efficiency and charge transport level.

With such a configuration, the power generating semiconductor part 47, etc., of the organic electroluminescent device 3 more efficiently generates a charge based on the internal light L, making it possible to efficiently supply (inject) the generated charge to (into) the organic electroluminescent layer 49 (light-emitting layer). As a result, the organic electroluminescent layer 49 further suppresses power consumption, thereby further improving electroluminescent efficiency.

The organic electroluminescent device 3, etc., having the built-in power generating device of the above embodiment is characterized in that the power generating semiconductor part 47, etc., is made of a bipolar semiconductor material.

With such a configuration, the layering employing the bipolar semiconductor material is easy, making it possible to simply form the power generating semiconductor part 47, etc.

The organic electroluminescent device 3, etc., having the built-in power generating device of the above embodiment is characterized in that the power generating semiconductor part 47, etc., is formed using one of a vapor deposition, evaporation deposition, coating method, a gel-sol method, sputtering method, and the like. With this arrangement, the power generating semiconductor part 47, etc., can be simply stacked using a general film formation technique.

### Modifications of the Organic Electroluminescent Device

The organic electroluminescent device 3, etc., of the above embodiment constitute a single layer film of the power generating semiconductor 47, etc., or a mixed film of a p-type semiconductor and n-type semiconductor.

That is, the organic electroluminescent device 3, etc., of each of the above embodiments is characterized in that it constitutes a single layer film of the power generating semiconductor part 47, etc. The organic electroluminescent device 3, etc., built into the display device 1, etc., of each of the above embodiments is characterized in that it constitutes a single layer film of the power generating semiconductor part 47, etc. The organic electroluminescent device 3, etc., having a built-in power generating device of the above embodiment is characterized in that it constitutes a single layer film of the power generating semiconductor part 47, etc.

Such a configuration makes it possible to combine the processes of absorption of internal light using one type of material, light to charge carrier separation, charge carrier transport within the film, and charge carrier injection into a neighboring layer, and simplifies the film formation procedure. Note that the term single layer film may also refer to a concept that includes a mixed film.

That is, the organic electroluminescent device 3, etc., of the above embodiment is characterized in that the power generating semiconductor part 47, etc., is a mixed film of a p-type semiconductor and an n-type semiconductor. The organic electroluminescent device 3, etc., built into the display device 1, etc., of the above embodiment is characterized in that the power generating semiconductor part 47, etc., is a mixed film of a p-type semiconductor and an n-type semiconductor. The organic electroluminescent device 3, etc., having the built-in power generating device of the above embodiment is characterized in that the power generating semiconductor part 47, etc., is a mixed film of a p-type semiconductor and an n-type semiconductor.

According to such a configuration, in a case where it is difficult to combine the processes of absorption of the internal light L using a single type of material, light to charge carrier separation, charge carrier transport within the film, and charge carrier injection to a neighboring layer, the function of the photoelectric conversion film of the power generating semiconductor part 47 may be enhanced by supplementing each function by mixing various types of materials.

The organic electroluminescent device 3, etc., of the above embodiment is characterized in that the power generating semiconductor part 47, etc., is a stacked structure of an n-type semiconductor layer and a p-type semiconductor layer. The organic electroluminescent device 3, etc., built into the display device 1, etc., of the above embodiment is characterized in that the power generating semiconductor part 47, etc., is a stacked structure of an n-type semiconductor layer and a p-type semiconductor layer. The organic electroluminescent device 3, etc., having a built-in power generating device of the above embodiment is characterized in that the power generating semiconductor part 47, etc., is a stacked structure of an n-type semiconductor layer and a p-type semiconductor layer.

In a case where a variety of materials are mixed together, control such as density adjustment may be difficult, but stacking the materials as described above enhances the effects of the power generating semiconductor part (photoelectric conversion film) exhibited by each function, namely absorption of internal light, light to charge carrier separation, charge carrier transport within the film, and charge carrier injection to a neighboring layer.

Note that the power generating semiconductor part 47, etc., may utilize not only a single layer film, mixed film, or stacked film such as described above, but also a structure that combines a mixed film and stacked film. Possible examples of such a stacked structure include, for example, the power generating semiconductor part 47, etc, having a stacked p-type semiconductor layer and p-type semiconductor layer, or a stacked n-type semiconductor layer and n-type semiconductor layer. With such an arrangement, each of the functions is supplemented by the mixed film and stacked film, making it possible to improve the photoelectric conversion efficiency of the power generating semiconductor part 47, etc.

The organic electroluminescent device 3b of embodiment 3 having the built-in power generating device is characterized in that it further comprises the buffer layer 55 that promotes the injection of a charge to the power generating semiconductor part 53, between at least one of the plurality of electrodes 46 and 52 (anode, cathode) and the power generating semiconductor part 53.

According to such a configuration, the power generating semiconductor part 53 is capable of readily accepting the charge of at least one of the plurality of electrodes 46 and 52 due to the existence of the buffer layer 55, thereby improving electroluminescent efficiency.

While each of the above embodiments has described an illustrative scenario of a stacked structure of the organic electroluminescent device 3, etc., the stacked structure is not limited thereto, allowing use of a stacked structure such as described below, from the glass substrate 45.

While each of the above embodiments has described an illustrative scenario of a single organic electroluminescent device 3, etc., a structure such as described below, for example, is also acceptable. That is, in a case where a plurality of stacked structures (a plurality of combinations of the hole injection layer 47/hole transport layer 48/light-emitting layer 49/electron transport layer 50/electron injection layer 51) is used between the plurality of electrodes 46 and 53, the single organic electroluminescent device 3, etc., may take on a form wherein each stacked structure is arranged in a number of layers while inserting the power generating semiconductor part 53 therebetween. Note that the order of arrangement of the stacked structure may be reversed as well.

In each of the above embodiments, the layers may also be stacked in the order of the anode 46/power generating semiconductor part 53 (photoelectric conversion film)/hole injection layer 47/hole transport layer 48/light-emitting layer 49/electron transport layer 50/electron injection layer 51/power generating semiconductor part 53 (photoelectric conversion film)/hole injection layer 47/hole transport layer 48/light-emitting layer 49/electron transport layer 50/electron injection layer 51/cathode 52, from the glass substrate 45.

Or, in each of the above embodiments, the layers may be stacked in the order of the anode 46/power generating semiconductor part 53 (photoelectric conversion film)/light-emitting layer 49/power generating semiconductor part 53 (photoelectric conversion film)/light-emitting layer 49/electron transport layer 50/electron injection layer 51/cathode 52, from the glass substrate 45.

In each of the above embodiments, the organic electroluminescent device 3, etc., may also take on a form wherein the power generating semiconductor part 53 is inserted between each layer so that the layers are stacked in the order of the anode 46/power generating semiconductor part 53/light-emitting layer 49/power generating semiconductor part 53/light-emitting layer 49/power generating semiconductor part 53/ . . . (omitted) . . . /cathode 52, from the glass substrate 45.

While the above embodiment describes an illustrative scenario in which the power generating semiconductor part 53 is mainly stacked on a layer between the cathode 52 and the anode 46, the present invention is not limited thereto. That is, the power generating semiconductor part 53 may not only be stacked between the cathode 52 and the anode 46, but also arranged in any position within the organic electroluminescent device 3, etc. For example, the power generating semiconductor part 53 may be arranged on the barrier 54, the anode 46, the glass substrate 45, or the side section 41, or any combination thereof.

Note that the side section 41 of the power generating semiconductor part is not limited to the examples shown in the figure described above, and may be a useless section unrelated to the removal of light when each of the layers 47, etc., is formed. This side section 41 may be formed not only on the right side as illustrated in the figure, but also on the left side or only on the left side.

In the organic electroluminescent device 3, etc., of the above embodiment, setting the layer that is to serve as the power generating semiconductor part as the hole transport layer 48 (or the electron transport layer 50) located closer to the light-emitting layer 49 than the hole injection layer 47 (or the electron injection layer 51), for example, makes it possible for this layer serving as the power generating semiconductor part to more efficiently utilize the internal light and produce a new charge, thereby further improving electroluminescent efficiency. At this time, in the organic electroluminescent device 3, etc., of the above embodiment, it is also possible to remove the internal light that originally could not be removed to the outside and utilized, thereby improving contrast.

In the organic electroluminescent device 3, etc., of the above embodiment, the organic electroluminescent layer 49 (light-emitting layer) may be stacked in a plurality of locations between the plurality of electrodes 46 and 52.

In the organic electroluminescent device 3, etc., of the display device 1, etc., of the above embodiment, the organic electroluminescent layer 49 (light-emitting layer) may be stacked in a plurality of locations between the plurality of electrodes 46 and 52.

In the organic electroluminescent device 3, etc., of the power generating device of the above embodiment, the organic electroluminescent layer 49 (light-emitting layer) may be stacked in a plurality of locations between the plurality of electrodes 46 and 52.

With such a configuration, not only does the amount of light from the organic electroluminescent layer 49 increase, but the power generating semiconductor part 47, etc., absorbs a greater amount of the internal light L from the organic electroluminescent layer 49 stacked in a plurality of locations, making it possible to produce a larger new charge and generate power based on this absorbed light.

The organic electroluminescent device 3, etc., of each of the above embodiments is characterized in that the material components of the power generating semiconductor part 53 comprise an organic semiconductor material that contains π electrons or a pigment functional material, and is made of an inorganic semiconductor compound of GaAs or the like, or an oxide semiconductor of ZnO or TiO or the like.

The display device 1, etc., of each of the above embodiments is characterized in that the organic electroluminescent device 3, etc. is designed so that the material components of the power generating semiconductor part 53 comprise an organic semiconductor material that contains π electrons or a pigment functional material, and constitute an inorganic semiconductor compound of GaAs or the like, or an oxide semiconductor of ZnO or TiO or the like.

The power generating device of each of the above embodiments is characterized in that the organic electroluminescent device 3, etc., is designed so that the material components of the power generating semiconductor part 53 comprise an organic semiconductor material that contains π electrons or a pigment functional material, and constitute an inorganic semiconductor compound of GaAs or the like, or an oxide semiconductor of ZnO or TiO or the like.

While the above embodiment utilizes the refractive index difference between the power generating semiconductor part 47, etc., and each layer above and below that layer, it is also possible to utilize the ease at which the internal light is guided within the power generating semiconductor part 47, etc., (photoelectric conversion unit) in a case where the power generating semiconductor part 47, etc., has a refractive index that is higher than the periphery layers (the layers above and below the power generating semiconductor part 47, etc.), for example. That is, in this embodiment, in addition to the aforementioned configuration, the power generating semiconductor part 47, etc., has a higher refractive index than the periphery layers. With this arrangement, once the internal light enters inside the power generating semiconductor part 47, etc., the internal light readily accumulates within the power generating semiconductor 47, etc., enabling the power generating semiconductor 47, etc., to use this internal light to reduce its internal power consumption.

Additionally, in the above embodiment, it is also possible to employ a form comprising a compensating layer that diffuses and reflects the internal light L from the film of at least either that upper layer or lower layer directly facing the power generating semiconductor part 47, etc., to at least either that upper layer or that lower layer.

1-54. (canceled)

55. An organic electroluminescent device comprising:
a plurality of electrodes stacked on a substrate, at least one of said electrodes being transparent or semi-transparent; an organic electroluminescent layer that is stacked between said plurality of electrodes and emits light by means of an electric field generated between said plurality of electrodes by an applied voltage; and a power generating semiconductor part that is arranged on the periphery of said organic electroluminescent layer, and utilizes an internal light among the light emitted by said organic electroluminescent layer in order to generate power by a photoelectric conversion function, said internal light not having been emitted from said transparent or semi-transparent electrode to the outside but remains inside.

56. The organic electroluminescent device according to claim 55, wherein: said power generating semiconductor part is one of an organic semiconductor, an inorganic semiconductor, and an oxide semiconductor.

57. The organic electroluminescent device according to claim 55, wherein: said power generating semiconductor part is stacked as a layer between said plurality of electrodes.

58. The organic electroluminescent device according to claim 57, wherein: said power generating semiconductor part is an electron injection layer, or an electron transport layer, or a hole transport layer, or a hole injection layer, or a combination of at least one of the electron injection layer, the electron transport layer, the hole transport layer, and the hole injection layer, formed between said plurality of electrodes.

59. The organic electroluminescent device according to claim 57, wherein: said power generating semiconductor part is made of such material that a difference of a refractive index of the material and a refractive index of said layer that is a neighboring layer on the side where said internal light enters is a predetermined value or higher.

60. The organic electroluminescent device according to claim 55, wherein: said power generating semiconductor part is stacked closer to said transparent or semi-transparent electrode than said organic electroluminescent layer.

61. The organic electroluminescent device according to claim 55, wherein: said power generating semiconductor part is formed in multiple layers respectively corresponding to the color of said internal light, between said plurality of electrodes.

62. The organic electroluminescent device according to claim 55, wherein: said organic electroluminescent layer is stacked in a plurality of locations between said plurality of electrodes.

63. The organic electroluminescent device according to claim 55, wherein: said power generating semiconductor part is made of a material that absorbs said internal light within a specific wavelength range.

64. The organic electroluminescent device according to claim 63, wherein: said power generating semiconductor part is made of said material that absorbs said internal light within said specific wavelength range from an ultraviolet area to an infrared area.

65. The organic electroluminescent device according to claim 55, wherein: said power generating semiconductor part is a film having a high charge separation efficiency and a high charge transport level.

66. The organic electroluminescent device according to claim 55, wherein: said power generating semiconductor part is made of a bipolar semiconductor material.

67. The organic electroluminescent device according to claim 66, wherein: said power generating semiconductor part is a single layer.

68. The organic electroluminescent device according to claim 55, wherein: said power generating semiconductor part is a mixed film comprising a p-type semiconductor and an n-type semiconductor.

69. The organic electroluminescent device according to claim 55, wherein: said power generating semiconductor part has a structure wherein an n-type semiconductor and a p-type semiconductor are stacked.

70. The organic electroluminescent device according to claim 55, further comprising a buffer layer disposed between at least one of said plurality of electrodes and said power generating semiconductor part, for promoting the injection of a charge to said power generating semiconductor part.

71. The organic electroluminescent device according to claim 55, wherein: a material component of said power generating semiconductor part is an organic semiconductor material containing π electrons or pigment functional material, and is made of an inorganic semiconductor compound or an oxide semiconductor.

72. The organic electroluminescent device according to claim 55, wherein: said power generating semiconductor part is formed by one of a vapor deposition, evaporation deposition, coating method, sol-gel method, and sputtering method.

73. A display device comprising:
a display panel having an organic electroluminescent device; and
a driving circuit, said organic electroluminescent device including: a plurality of electrodes stacked on a substrate, at least one of said electrodes being transparent or semi-transparent; an organic electroluminescent layer that is stacked between said plurality of electrodes and emits light by means of an electric field generated between said plurality of electrodes by an applied voltage, and a power generating semiconductor part that is arranged on the periphery of said organic electroluminescent layer, and utilizes an internal light among the light emitted by said organic electroluminescent layer in order to generate power by a photoelectric conversion function, said internal light not having been emitted from said transparent or semi-transparent electrode to the outside but remains inside;
and said driving circuit providing an applied voltage between said plurality of electrodes in accordance with inputted image data so as to drive each of said organic electroluminescent devices of said display panel.

74. The display device according to claim 73, wherein:
said organic electroluminescent device is included in said display device, and said power generating semiconductor part of said organic electroluminescent device is an organic semiconductor or an inorganic semiconductor.

75. The display device according to claim 73, wherein:
said organic electroluminescent device is included in said display device, and said power generating semiconductor part of said organic electroluminescent device is stacked as a layer between said plurality of electrodes.

76. The display device according to claim 75, wherein:
said organic electroluminescent device is included in said display device, and said power generating semiconductor part of said organic electroluminescent device is an electron injection layer, or an electron transport layer, or a hole transport layer, or a hole injection layer, or a combination of at least one of the electron injection layer, the electron transport layer, the hole transport layer, and the hole injection layer, formed between said plurality of electrodes.

77. The display device according to claim 75, wherein:
said organic electroluminescent device is included in said display device, and said power generating semiconductor part of said organic electroluminescent device is made of such material that a difference of a refractive index of the material and a refractive index of said layer that is a neighboring layer on the side where said internal light enters is a predetermined value or higher.

78. The display device according to claim 73, wherein:
said organic electroluminescent device is included in said display device, and said power generating semiconductor part of said organic electroluminescent device is stacked closer to said transparent or semi-transparent electrode than said organic electroluminescent layer.

79. The display device according to claim 73, wherein:
said organic electroluminescent device is included in said display device, and said power generating semiconductor part of said organic electroluminescent device is formed in multiple layers respectively corresponding to the color of said internal light, between said plurality of electrodes.

80. The display device according to claim 73, wherein:
said organic electroluminescent device is included in said display device, and said organic electroluminescent layer of said organic electroluminescent device is stacked in a plurality of locations between said plurality of electrodes.

81. The display device according to claim 73, wherein:
said organic electroluminescent device is included in said display device, and said power generating semiconductor part of said organic electroluminescent device is made of a material that absorbs said internal light within a specific wavelength range.

82. The display device according to claim 81, wherein:
said organic electroluminescent device is included in said display device, and said power generating semiconductor part of said organic electroluminescent device is made of said material that absorbs said internal light within said specific wavelength range from an ultraviolet area to an infrared area.

83. The display device according to claim 73, wherein:
said organic electroluminescent device is included in said display device, and said power generating semiconductor part of said organic electroluminescent device is a film having a high charge separation efficiency and a high charge transport level.

84. The display device according to claim 73, wherein:
said organic electroluminescent device is included in said display device, and said power generating semiconductor part of said organic electroluminescent device is made of a bipolar semiconductor material.

85. The display device according to claim 84, wherein:
said organic electroluminescent device is included in said display device, and said power generating semiconductor part of said organic electroluminescent device is a single layer.

86. The display device according to claim 73, wherein:
said organic electroluminescent device is included in said display device, and said power generating semiconductor part of said organic electroluminescent device is a mixed film comprising a p-type semiconductor and an n-type semiconductor.

87. The display device according to claim 73, wherein:
said organic electroluminescent device is included in said display device, and said power generating semiconductor part of said organic electroluminescent device has a structure wherein an n-type semiconductor and a p-type semiconductor are stacked.

88. The display device according to claim 73, wherein:
said organic electroluminescent device is included in said display device and further has a buffer layer disposed between at least one of said plurality of electrodes and said power generating semiconductor part, for promoting the injection of a charge to said power generating semiconductor part.

89. The display device according to claim 73, wherein:
said organic electroluminescent device is included in said display device, and a material component of said power generating semiconductor part of said organic electroluminescent device is an organic semiconductor material containing π electrons or pigment functional material, and is made of an inorganic semiconductor compound or an oxide semiconductor.

90. The display device according to claim 73, wherein:
said organic electroluminescent device is included in said display device, and said power generating semiconductor part of said organic electroluminescent device is formed by one of a vapor deposition, evaporation deposition, coating method, sol-gel method, and sputtering method.
